(19) United States
(12) Patent Application Publication
(10) Pub. No.: US 2007/0189058 A1
(43) Pub. Date: Aug. 16, 2007

(54) Molecular system and method for reversibly switching the same between four states

(76) Inventors: Zhang-Lin Zhou, Palo Alto, CA (US); Kent D. Vincent, Cupertino, CA (US); Sean X. Zhang, Cupertino, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/352,553

(22) Filed: Feb. 13, 2006

(51) Int. Cl. G11C 11/00

(52) U.S. Cl. 365/151; 977/709

(57) ABSTRACT

A molecular system that is reversibly switchable between four states includes two or more ends. At least three rotors and at least two stators are located between the ends. Each of the rotors is capable of rotating when under the influence of an electric field having a predetermined strength. The predetermined strength of the electric field for rotating one of the rotors is different than that of the predetermined strength of the electric field for rotating each of the other rotors. One or more conjugated connecting units links at least one of the at least three rotors and at least one of the at least two stators. The rotation of at least one of the at least three rotors switches the molecular system to one of the four states.

### BACKGROUND

The present disclosure relates generally to molecular systems, and more particularly to methods of reversibly switching the molecular systems between four states.

Molecular electronics is a relatively new field that includes the use of individual molecules and molecular systems to perform a variety of functions (e.g., switching) at the micro- and nano-scale level. The use of molecules to perform such functions enables the fabrication of devices having micrometer-scale or nanometer-scale dimensions, thus extending technology to sizes not easily achievable with present semiconductor technology.

Using the interplay of chemical, electrical, and/or optical signals, the molecules may be designed to execute three basic logic operations (AND, NOT, OR) and simple combinations thereof. Under the influence of an appropriate input stimulation, chemical systems may switch from one form to another, thus producing a change in detectable output. The detectable output is often exhibited by a color change. These molecular switches may exhibit dye-like optical properties and are capable of switching between two colors. The two colors that are exhibited by these systems,. may, in some instances, limit the use of such systems.

As such, it would be desirable to provide a molecular switch capable of switching between more than two states, thus exhibiting more than two colors.

### SUMMARY

A molecular system that is reversibly switchable between four states is disclosed. The molecular system includes two or more ends. At least three rotors and at least two stators are located between the ends. Each of the rotors is capable of rotating when under the influence of an electric field having a predetermined strength. The predetermined strength of the electric field for rotating one of the rotors is different than that of the predetermined strength of the electric field for rotating each of the other rotors. One or more conjugated connecting units link at least one of the three rotors and at least one of the two stators. The rotation of at least one of the three rotors switches the molecular system to one of the four states.

### BRIEF DESCRIPTION OF THE DRAWINGS

Features and advantages of the present disclosure will become apparent by reference to the following detailed description and drawings, in which like reference numerals correspond to similar, though not necessarily identical components. For the sake of brevity, reference numerals or features having a previously described function may not necessarily be described in connection with other drawings in which they appear.

FIG. 1 is a schematic diagram depicting an embodiment of a method of reversibly switching a generic molecular system between four states;

FIG. 2 is a schematic diagram depicting an embodiment of a method of reversibly switching a molecular system between four states;

FIG. 3 is a schematic diagram depicting an example of a molecular system reversibly switching between four states;

FIG. 4A is a schematic representation of two crossed wires, with at least one molecular system at the intersection of the two wires; and

FIG. 4B is a perspective elevational schematic view, depicting the crossed-wire device shown in FIG. 4A.

### DETAILED DESCRIPTION

Embodiments of the present disclosure advantageously provide a new type of molecular system that is switchable between four states and is capable of exhibiting different colors. Generally, the availability of multi-colors with the molecular system may make the display devices in which the system is used simpler and thus more cost efficient. Embodiments of the molecular system disclosed herein are capable of both optical and/or electrical switching. The molecular systems have a functional length measured in nanometers, or larger (e.g. micrometers), and thus are suitable for use in a variety of optical and/or electronic devices.

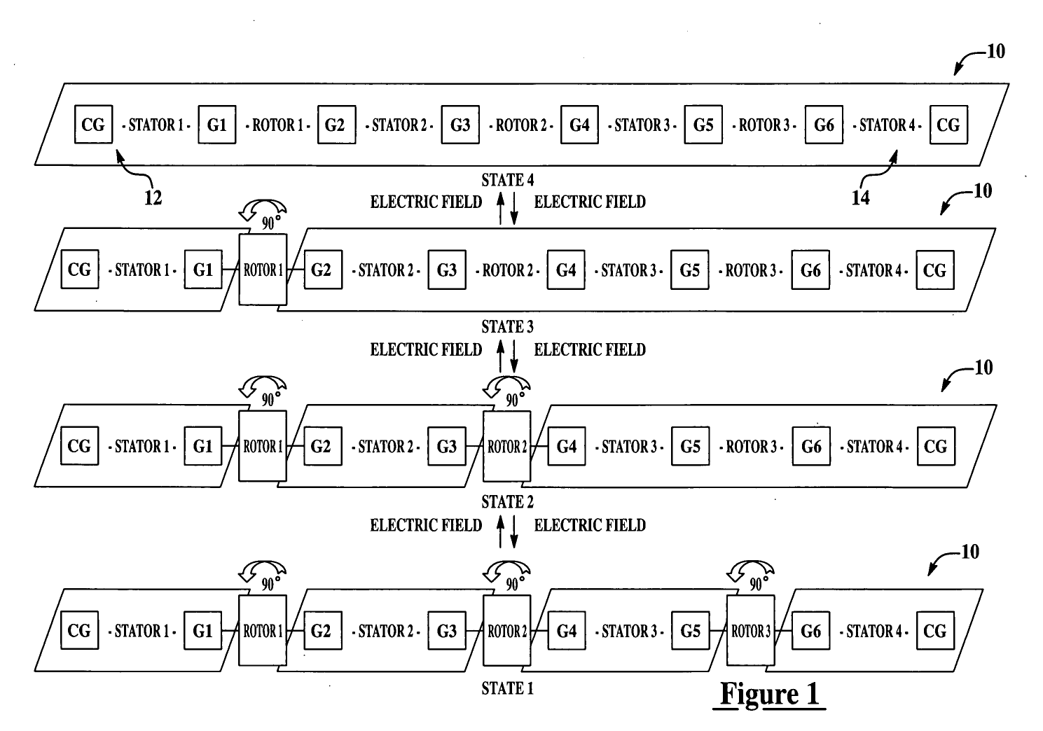

Referring now to FIG. 1, a generic molecular system 10 that is capable of reversibly switching between four states is depicted. Generally, the molecular system 10 includes at least three rotors ROTORn (where “n” is an integer) at least two stators STATORn (where “n” is an integer) and at least one conjugated connecting unit Gn (where “n” is an integer) linking a rotor ROTOR1, ROTOR2, ROTOR3 to a stator STATOR1, STATOR2, STATOR 3, STATOR4. The ends 12, 14 of the molecular system 10 may include a connecting group CG, which may constitute the end 12, 14 of the molecular system 10 or may be connected to some other suitable end group.

Each of the rotors ROTOR1, ROTOR2, ROTOR3 is capable of rotating when under the influence of an electric field having a predetermined strength. It is to be understood that the predetermined strength of the electric field suitable for rotating one of the three rotors ROTOR1, ROTOR2, ROTOR3 is different than that of the predetermined strength of the electric field for rotating each of the other of the rotors ROTOR1, ROTOR2, ROTOR3. As such, the strength of the electric field depends, at least in part, on the rotors ROTOR1, ROTOR2, ROTOR3 in the molecular system 10. In an embodiment, the electric field used to rotate one rotor ROTOR1 ranges from about 0.004 eV to about 0.008 eV (0.1 to 0.2 kcal/mole); the electric field used to rotate a second rotor ROTOR2 is equal to or greater than about 0.02 eV (about 0.5 kcal/mole); and the electric field used to rotate a third rotor ROTOR3 is equal to or greater than about 0.04 eV (0.9 kcal/mole).

Generally, the rotors ROTOR1, ROTOR2, ROTOR3 are rotatable segments that have a large dipole moment and that link other portions of the molecular system 10 that are immobilized (e.g., the stators). Under the influence of an applied electric field, the vector dipole moment of the rotor(s) ROTOR1, ROTOR2, ROTOR3 attempts to align parallel to the direction of the external field. Each of the rotors ROTOR1, ROTOR2, ROTOR3 has a large dipole moment in a different environment. As such, an electric field that is capable of aligning the first rotor ROTOR1 is different than the electric field that is capable of aligning the second rotor ROTOR2, and both of these electric fields are different than the electric field that is capable of aligning the third rotor ROTOR3.

It is to be understood that the molecular system 10 is designed such that there are inter- and/or intramolecular forces, such as hydrogen bonding or dipole-dipole interactions as well as steric repulsions, which substantially stabilize the rotor(s) ROTOR1, ROTOR2, ROTOR3 in particular orientations with respect to the stator(s) STATOR1, STATOR2, STATOR3, STATOR4. Thus, different, relatively large fields may be used to unlatch the rotor(s) ROTOR1, ROTOR2, ROTOR3 from its initial orientation and rotate with respect to the stator(s) STATOR1, STATOR2, STATOR3, STATOR4, if the direction of the applied field is opposite to that of the dipole of the rotor ROTOR1, ROTOR2, ROTOR3.

Once switched into a particular orientation, the molecular system 10 remains in that orientation until exposure to an external field. Further, the molecular system 10 may include a steric repulsion that substantially prevents the rotors ROTOR1, ROTOR2, ROTOR3 from rotating through a complete 180° half cycle. The rotors' ROTOR1, ROTOR2, ROTOR3 rotation may be halted by the steric interaction of bulky groups on the rotors ROTOR1, ROTOR2, ROTOR3 and stators STATOR1, STATOR2, STATOR3, STATOR4 at an angle of approximately 90° from the initial orientation. Furthermore, this 90° orientation may be stabilized by a different set of inter- and/or intramolecular hydrogen bonds or dipole interactions, and is thus latched into place even after the applied field is turned off.

In FIG. 1, the molecular system 10 is in its planar (ON) state at STATE 4, where the rotors ROTOR1, ROTOR2, ROTOR3 and stator(s) STATOR1, STATOR2, STATOR3, STATOR4 are co-planar. In the planar state, the molecular system 10 is fully conjugated, is substantially colorless or evidences a hue (first spectral or red-shifted optical state), and is comparatively more electrically conductive. Thus, the π-electrons and the non-bonding electrons of the molecular system 10, through its highest occupied molecular orbital (HOMO) and lowest unoccupied molecular orbital (LUMO), are delocalized over substantially the entire system 10. This is a relatively highly conductive (switch ON) state for the molecular system 10.

FIG. 1 also illustrates the non-planar (OFF) states (e.g., STATE 1, STATE 2, and STATE 3) where one or more of the rotors ROTOR1, ROTOR2, ROTOR3 are rotated about 90° with respect to the stators STATOR1, STATOR2, STATOR3, STATOR4, which remain co-planar. In the OFF states, the conjugation of the molecular system 10 is broken. As a result, the molecular system 10 is substantially colorless or exhibits different hues (second spectral or blue-shifted optical states) from that exhibited in the ON state and each of the other OFF states, and is comparatively less electrically conductive. In the OFF states, the HOMO and LUMO are no longer delocalized over the entire molecular system 10. These are relatively low conductivity states of the molecular system 10.

As depicted, the state of the molecular system 10 may be altered by applying a different strength of applied external e-field. Additionally, the colors of the molecular system 10 may be tuned to be substantially transparent, blue, green, or red by selectively rotating the rotor(s) ROTOR1, ROTOR2 and/or ROTOR3.

It is to be understood that the labels STATE1, STATE2, STATE3 and STATE4 are merely illustrative of the four states that the molecule 10 may switch between. It is to be further understood that the labels are not necessarily indicative of the molecule's particular configuration. For example, a first state of the molecule 10 may be the co-planar state (labeled STATE 4 in FIG. 1), and a fourth state of the molecule 10 may have all three rotors ROTOR1, ROTOR2, ROTOR3 in an out-of-planar state with respect to the stators STATOR1, STATOR2 (labeled STATE 1 in FIG. 1).

Generally, the molecular system 10 tends to have all of the rotors ROTOR1, ROTOR2, ROTOR3 aligned with each other in an out-of-plane orientation with respect to the stators STATOR1, STATOR2, STATOR3, STATOR4, as shown in STATE 1. In this state, the molecular system 10 is strongly blue-shifted, is in a highly localized state, and exhibits a substantially colorless or transparent property.

Under the influence of an applied external field, one of the rotors ROTOR3 rotates to be substantially co-planar with the stators STATOR1, STATOR2, STATOR3, STATOR4, as shown in STATE 2. In this state, the rotor ROTOR3 aligns itself with the applied external electric field, while the other rotors ROTOR1, ROTOR2, remain in their out-of-planar orientation with the rest of the molecular system 10. With the rotation of the rotor ROTOR3, the molecular system 10 exhibits a blue color, due, at least in part, to the red-shifted absorption induced by partial delocalization of the molecular system 10. It is to be understood that the electric field applied to rotate one of the rotors ROTOR3 is generally smaller than the electric field applied to rotate the other rotors ROTOR1, ROTOR2.

In STATE 3, the applied electric field is capable of rotating two rotors ROTOR2, ROTOR3 such that they are co-planar with stators STATOR1, STATOR2, STATOR3, STATOR4. One of the rotors ROTOR1 remains out-of-plane with respect to the stators STATOR1, STATOR2, STATOR3, STATOR4. In STATE 3, the molecular system 10 exhibits another color, for example, a green color. It is to be understood that the electric field applied to achieve the rotation of two rotors ROTOR2, ROTOR3 is generally larger than that applied to rotate one of the rotors ROTOR3.

When a higher electric field is applied, the molecular system 10 is in STATE 4 where all three rotors ROTOR1, ROTOR2, ROTOR3 rotate to be co-planar with the stators STATOR1, STATOR2, STATOR3, STATOR4. In STATE 4, the molecular system 10 is completely conjugated and has the smallest band gap of all the states. The absorption of the molecular system 10 is red-shifted and a red color is exhibited.

It is to be understood that the terms “red shifted” and “blue shifted” as referred to herein are not meant to convey any relationship to hue, but rather to the direction in the electromagnetic energy spectrum of the energy shift of the gap between the HOMO and LUMO states.

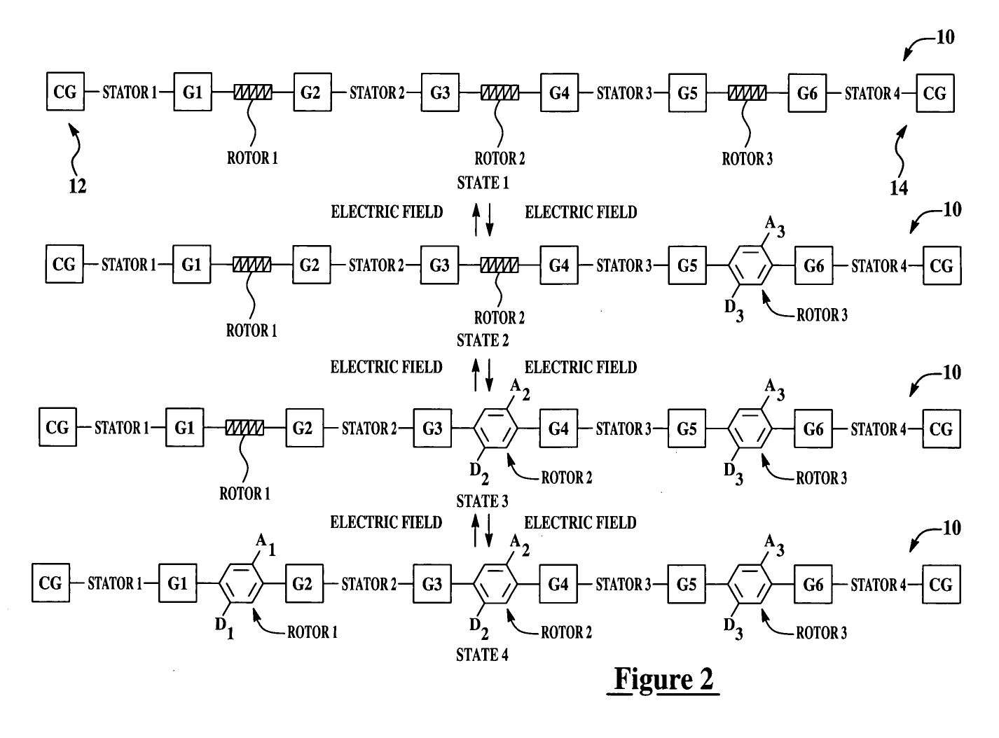

Referring now to FIG. 2, a semi-generic molecular system 10 is shown that is reversibly switchable between four states. As previously described, the molecular system 10 may be switched between the respective states and exhibit different hues when subjected to electric fields of different predetermined strengths.

In this embodiment, connecting groups CG are located at the ends 12, 14 of the molecular system 10. The connecting groups CG may be configured to connect the molecular system 10 to another molecular system 10 or to a suitable substrate. It is to be understood that the connecting groups CG may be a single unit or multiple units linked together. Non-limitative examples of suitable connecting groups CG include hydrogen; hetero atoms including at least one of C, N, O, S, and P; functional groups containing at least one of the hetero atoms; saturated hydrocarbons; unsaturated hydrocarbons; substituted hydrocarbons; and combinations thereof.

The rotors ROTOR1, ROTOR2, ROTOR3 are molecules that include an electron-accepting group A₁, A₂, A₃ and an electron-donating group D₁, D₂, D₃. It is to be understood that the electron-accepting group A₁, A₂, A₃ is an electron-withdrawing group. In an embodiment, the electron-accepting group A₁, A₂, A₃ is at least one of hydrogen; hetero atoms including at least one of N, O, S, P, F, Cl, and Br; functional groups containing at least one of the hetero atoms; saturated hydrocarbons; unsaturated hydrocarbons; substituted hydrocarbons; carboxylic acids; carboxylic esters; carboxylic amides; nitro groups; nitrites; carbonyls; cyano groups; imines; azo groups; sulfuric acids; sulfuric esters; sulfuric amides; phosphoric acids; phosphoric esters; phosphoric amides; and combinations thereof.

The electron-donating group D₁, D₂, D₃ is at least one of functional groups containing at least one hetero atom including at least one of B, Si, I, N, O, S, and P; hydrogen; amines; OH; SH; ethers; saturated hydrocarbons; unsaturated hydrocarbons; substituted hydrocarbons; and combinations thereof. It is to be understood that the electron-donating group D₁, D₂, D₃ is less electronegative, or more electropositive, than the electron-accepting group A₁, A₂, A₃.

Specific non-limitative examples of rotors ROTOR1, ROTOR2, ROTOR3 include aromatic hydrocarbons, poly-aromatic hydrocarbons, substituted aromatic hydrocarbons, poly-aromatic hydrocarbons, aromatic heterocycles, poly-aromatic heterocycles, substituted aromatic heterocycles, poly-aromatic heterocycles, or the like, or combinations thereof.

The stator(s) STATOR1, STATOR2, STATOR3, STATOR4 are generally geometrically fixed conjugating systems. In the embodiment as depicted in FIG. 2, the stator(s) STATOR1, STATOR2, STATOR3, STATOR4 are linked to the rotor(s) ROTOR1, ROTOR2, ROTOR3, one of which may be the middle segment of the molecular system 10. The stator(s) STATOR1, STATOR2, STATOR3, STATOR4 may be aromatic hydrocarbons, poly-aromatic hydrocarbons, substituted aromatic hydrocarbons, substituted poly-aromatic hydrocarbons, aromatic heterocycles, poly-aromatic heterocycles, substituted aromatic heterocycles, substituted poly-aromatic heterocycles, unsaturated hydrocarbons, saturated hydrocarbons, substituted hydrocarbons, or combinations thereof. Specific non-limitative examples of suitable stators STATOR1, STATOR2, STATOR3, STATOR4 include benzene derivatives, substituted benzene derivatives, naphthalene derivatives, substituted naphthalene derivatives, anthracene derivatives, substituted anthracene derivatives, pyridine derivatives, substituted pyridine derivatives, and combinations thereof. Examples of derivatives include, but are not limited to phenanthrene, pyrrole, furan, thiophene, imidazole, benzimidazole, oxazole, thiazole, pyrazole, pyridine, pyrimidine, purine, quinoline, isoquinoline, carbazole, indolizine, indole, isoindole, indoline, benzofuran, benzothiophene, indazole, benzindazole, benzthiazole, quinolizine, cinnoline, phthalazine, quinazoline, quinoxaline, naphthyridine, pteridine, indene, azulene, isoxazole, isothiazole, oxadiazole, triazole, thiadiazole, pyran, pyridazine, pyrazine, triazine, and combinations thereof.

The stator STATOR1, STATOR2, STATOR3, STATOR4 hydrocarbon units may contain conjugated rings and/or at least one hetero atom including S, N, and/or O. The conjugated rings may contribute to the extended conjugation of the molecular system 10 when it is in its ON state. The conjugated rings of the stator(s) STATOR1, STATOR2, STATOR3, STATOR4 may include spacing group(s) (not shown). In an embodiment, the spacing group may be linked to any position on the conjugated ring, such as the 2, 3, 5, and 6 positions of a substituted benzene derivative. In a non-limitative example, the spacing group is located at the ortho, para or meta position of the stator STATOR1, STATOR2, STATOR3, STATOR4 in relationship to the connection site of the rotor ROTOR1, ROTOR2, ROTOR3.

Non-limitative examples of spacing group(s) include phenyls, diphenylmethyl groups, substituted diphenylmethyl groups (non-limitative examples of which include di(2-methylphenyl)methyl groups, di(2-ethylphenyl)methyl groups, di(2-propylphenyl)methyl groups, di(2-butylphenyl)methyl groups, di(2-tert-butylphenyl)methyl groups, di(3-methylphenyl)methyl groups, di(3-ethylphenyl)methyl groups, di(3-propylphenyl)methyl groups, di(3-butylphenyl )methyl groups, di(3-tert-butylphenyl )methyl groups, di(4-methylphenyl)methyl groups, di(4-ethylphenyl)methyl groups, di(4-propylphenyl)methyl groups, di(4-butylphenyl)methyl groups, di(4-tert-butylphenyl)methyl groups, di(5-methylphenyl)methyl groups, di(5-ethylphenyl)methyl groups, di(5-propylphenyl)methyl groups, di(5-butylphenyl)methyl groups, di(5-tert-butylphenyl)methyl groups, di(6-methylphenyl)methyl groups, di(6-ethylphenyl)methyl groups, di(6-propylphenyl)methyl groups, di(6-butylphenyl)methyl groups, di(6-tert-butylphenyl)methyl groups, and combinations thereof), arylalkyl groups, substituted arylalkyl groups (non-limitative examples of which include halogen substituted arylalkyl groups, and arylalkyl groups substituted with one or more of phenylmethyl groups, (2-methyl)phenylmethyl groups, (2-ethyl)phenylmethyl groups, (2-propyl)phenylmethyl groups, (2-butyl)phenylmethyl groups, (2-tert-butyl)phenylmethyl groups, (3-methyl)phenylmethyl groups, (3-ethyl )phenylmethyl groups, (3-propyl)phenylmethyl groups, (3-butyl)phenylmethyl groups, (3-tert-butyl)phenylmethyl groups, (4-methyl)phenylmethyl groups, (4-ethyl)phenylmethyl groups, (4-propyl)phenylmethyl groups, (4-buthyl)phenylmethyl groups, (4-tert-butyl)phenylmethyl groups, (5-methyl)phenylmethyl groups, (5-ethyl)phenylmethyl groups, (5-propyl)phenylmethyl groups, (5-buthyl)phenylmethyl groups, (5-tert-butyl)phenylmethyl groups, (6-methyl)phenylmethyl groups, (6-ethyl)phenylmethyl groups, (6-propyl)phenylmethyl groups, (6-buthyl)phenylmethyl groups, (6-tert-butyl)phenylmethyl groups, and combinations thereof), diaryl alkyl groups, substituted diaryl alkyl groups (non-limitative examples of which include halogen substituted diaryl alkyl groups, and diaryl alkyl groups substituted with diphenylmethyl groups, such as those previously described), alkyl groups, substituted alkyl groups (non-limitative examples of which include halogen substituted alkyl groups, and alkyl groups substituted with diphenylmethyl groups, such as those previously described), isopropyl groups, tert-butyl groups, tri-alkyl groups, and/or combinations thereof.

The spacing groups may generally be used to provide a desired three-dimensional scaffolding which advantageously allows the molecules to consolidate together while providing space for each rotor(s) ROTOR1, ROTOR2, ROTOR3 to rotate over a desired range of motion.

The molecular system 10 may further include conjugated connecting units (i.e. bridging group(s)) Gn (where “n” is an integer) that connect the stators STATOR1, STATOR2, STATOR3, STATOR4 to the rotors ROTOR1, ROTOR2, ROTOR3, the stators STATOR1, STATOR2, STATOR3, STATOR4 and/or rotors ROTOR1, ROTOR2, ROTOR3 to the connecting groups CG, and/or two or more conjugated rings connected to each other or to the connecting groups CG to achieve desired optical and/or electrical properties.

Non-limitative examples of suitable conjugated connecting units Gn include hydrogen, hetero atoms including one or more of C, N, O, S, and P, acetylenes, substituted acetylenes, ethylenes, substituted ethylenes, amides, imides, imines, azo groups, and combinations thereof. The conjugated connecting units Gn may alternately include a single atom bridge, such as an ether bridge with an oxygen atom, or a direct sigma bond between the rotors ROTOR1, ROTOR2, ROTOR3 and the stators STATOR1, STATOR2, STATOR3, STATOR4.

Generally, in embodiments of the molecular system 10 disclosed herein, each of the rotors ROTOR1, ROTOR2, ROTOR3 may have angularly offset sides to which the conjugated connecting unit(s) Gn may be attached, and the stators STATOR1, STATOR2, STATOR3, STATOR4 may have angularly offset positions to which the conjugated connecting unit(s) Gn may be attached. The angularly offset sides or positions may be at any suitable angle relative to each other, including, but not limited to 90° apart and/or 180° apart. In an embodiment, such as those depicted in FIGS. 1 and 2, the molecular system 10 is substantially linear, as the angularly offset sides of the rotors ROTOR1, ROTOR2, ROTOR3 to which the conjugated connecting groups Gn are attached are about 180° apart.

Referring now to FIGS. 1 and 2 together, there are four stators STATOR1, STATOR2, STATOR3, STATOR4. Each of the three rotors ROTOR1, ROTOR2, ROTOR3 has angularly offset sides, each of which is attached to a conjugated connecting unit Gn (specifically G1, G2, G3, G4, G5, G6). In these examples, the angularly offset sides are about 180° apart. Further, each of the conjugated connecting units Gn is also substantially linearly attached to one of the stators STATOR1, STATOR2, STATOR3, STATOR4. In these embodiments, the molecular system 10 has two ends/end regions 12, 14 with one or more connecting groups CG attached at each end 12, 14. The connecting groups CG are attached to two of the stators STATOR1, STATOR4 at a position distal to the position of the conjugated connecting units (specifically G1 and G6).

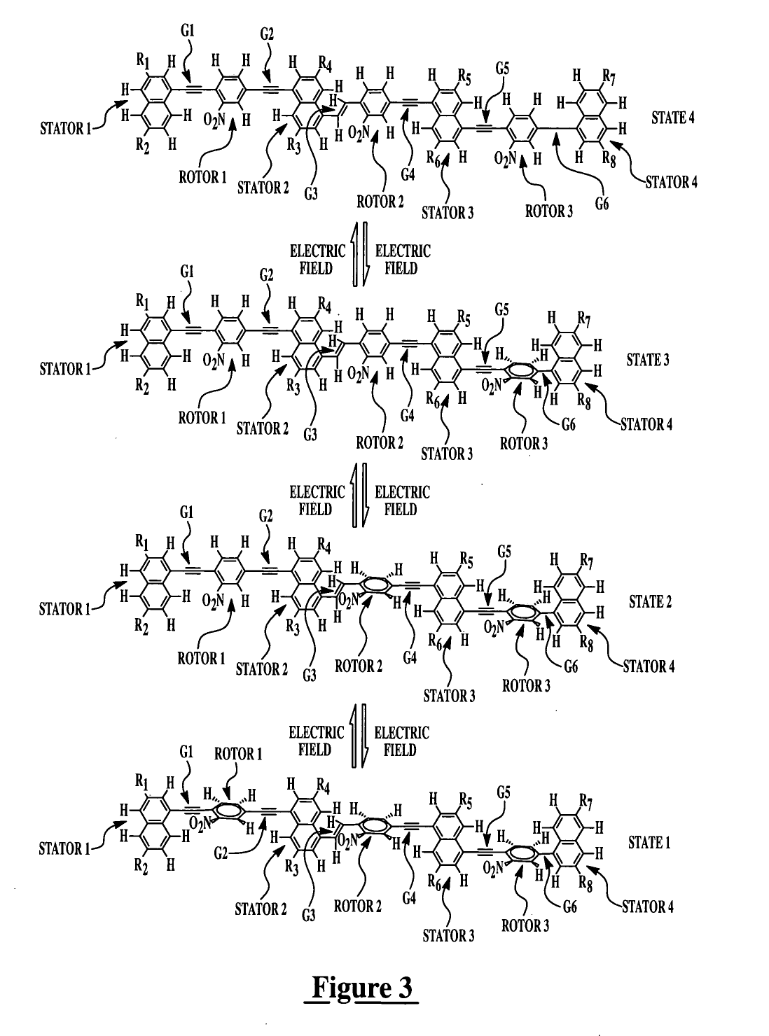

FIG. 3 depicts an example embodiment of a molecular system 10 switching between four states.

The stators STATOR1, STATOR2, STATOR3, STATOR4 in the molecular system 10 are substituted naphthalene rings. The substitution groups are depicted as Rₙ (where “n” is a number, e.g., R₁, R₂, R₃, R₄, R₅ ,R₆ ,R₇ and R₈). It is to be understood that the substitution groups Rₙ may be alkyl groups, substituted alkyl groups, aryl groups, substituted aryl groups, or the like, or combinations thereof.

The rotors ROTOR1, ROTOR2, ROTOR3 in the molecular system 10 are nitro-substituted benzene rings. The nitro group (N₂O) functions as the electron-accepting group A₁, A₂, A₃. One of the hydrogen groups (H) functions as the electron-donating group D₂, D₂, D₃.

In this non-limitative example, one rotor ROTOR1 is bonded to two stators STATOR1, STATOR2 with acetylene conjugated connecting units G1, G2. The acetylene conjugated connecting units G1, G2 have a free rotational nature, which allows the rotor ROTOR1 to feel less steric and electronic repulsion from the stators STATOR1, STATOR2. The energy barrier for the rotor ROTOR1 to switch in-plane or out-of-plane with the stators STATOR1, STATOR2 is minimal (about 0.1-0.2 kcal in a vacuum). As such, in this example molecular system 10, ROTOR1 is the rotor that switches the easiest, or with the weakest applied electric field.

The second rotor ROTOR2 is bonded to two stators STATOR2, STATOR3 via an ethene conjugated connecting unit G3 and an acetylene conjugated connecting unit G4. The steric and electronic repulsion between the rotor ROTOR2 and the stator STATOR2 is greater than that between the rotor ROTOR1 and the stators STATOR1, STATOR2 due to the nature of the ethene conjugated connecting unit G3. The energy barrier for the rotor ROTOR2 to switch in-plane or out-of-plane with stator STATOR2 is higher (at least about 0.5 kcal or more in a vacuum) than the energy barrier for rotor ROTOR1. Generally, the rotor ROTOR2 prefers to be in an out-of-plane orientation with respect to the stators STATOR1, STATOR2, STATOR3, STATOR4 in the absence of an external aligning force (e-field). In this example molecular system 10, ROTOR2 requires a higher external electric field than ROTOR1 to switch between states.

The third rotor ROTOR3 is bonded to two stators STATOR3, STATOR4 via an acetylene conjugated connecting unit G5 and a single carbon-carbon sigma bond conjugated connecting unit G6. The steric and electronic repulsion between the rotor ROTOR3 and the stator STATOR4 is greater than that between the rotor ROTOR2 and the stator STATOR2 due to the nature of the single carbon-carbon sigma bond conjugated connecting unit G6. The energy barrier for the rotor ROTOR3 to switch in-plane or out-of-plane with stators STATOR3, STATOR4 is the highest (at least about 0.9 kcal or more in a vacuum) among the three rotors ROTOR1, ROTOR2, ROTOR3 in the molecular system 10. Generally, this rotor ROTOR3 prefers an out-of-plane orientation with respect to the stators STATOR1, STATOR2, STATOR3, STATOR4 in the absence of a strong external aligning force (e-field). In other words, in this molecular system 10, ROTOR3 is the hardest of the three rotors ROTOR1, ROTOR2, ROTOR3 to switch between the states.

Generally, this particular molecular system 10 has all of the rotors ROTOR1, ROTOR2, ROTOR3 aligned with each other in an out-of-plane orientation with respect to the stators STATOR1, STATOR2, STATOR3, STATOR4, as shown in STATE 1. Each of the rotors ROTOR1, ROTOR2, ROTOR3 is in an OFF state. The molecular system 10 is strongly blue-shifted, is in a highly localized state, and exhibits a substantially colorless or transparent property.

Under the influence of an applied external field, the first rotor ROTOR1 rotates to be substantially co-planar with the stators STATOR1, STATOR2, STATOR3, STATOR4, as shown in STATE 2. Two of the rotors ROTOR2, ROTOR3 remain in an OFF state (out-of-plane), while ROTOR1 switches to the ON state by aligning itself with the applied external electric field. As previously described, the electric field applied to rotate ROTOR1 is smaller than that applied to rotate ROTOR2 and ROTOR3. With the rotation of the rotor ROTOR1, the molecular system 10 in STATE 2 exhibits a different color from that exhibited in STATE 1, for example, a blue color. The shift in color may be due, at least in part, to the red-shifted absorption induced by partial delocalization of the molecular system 10.

An electric field is applied to the molecular system 10 to switch from STATE 2 to STATE 3. The electric field is capable of rotating two rotors ROTOR1, ROTOR2, as such the electric field is larger than that applied to rotate one rotor ROTOR1. The rotors ROTOR1, ROTOR2 rotate so they are co-planar (ON state) with the stators STATOR1, STATOR2, STATOR3, STATOR4. One of the rotors ROTOR3 remains out-of-plane (OFF state) with respect to the stators STATOR1, STATOR2, STATOR3, STATOR4. With the rotation of the rotors ROTOR1, ROTOR2, the molecular system 10 in STATE 3 exhibits a different color from that exhibited in both STATE 1 and STATE2, for example, a green color.

When a higher electric field is applied, the molecular system 10 switches to STATE 4, where all three rotors ROTOR1, ROTOR2, ROTOR3 rotate to be co-planar with the stators STATOR1, STATOR2, STATOR3, STATOR4. In this co-planar or ON state, the molecular system 10 is completely conjugated and has the smallest band gap of all the states. The absorption of the molecular system 10 is red-shifted and a color is exhibited (e.g., red) that is different from the colors exhibited in all the other states.

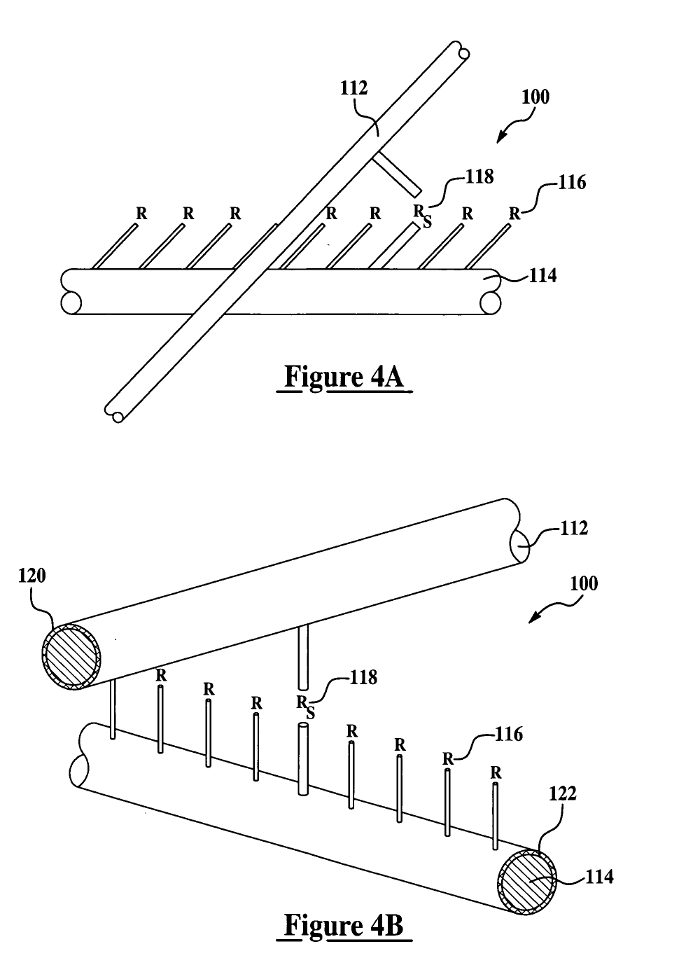

FIGS. 4A and 4B depict an embodiment of a molecular switching device 100 that includes two wires/electrodes 112, 114, each either a metal and/or semiconductor wire, that are crossed at some substantially non-zero angle. Disposed between wires 112, 114 is a layer 116 of molecules and/or molecular compounds, denoted R. The particular molecules 118 that are sandwiched at the intersection (also interchangeably referred to herein as a junction) of the two wires 112, 114 are identified as switch molecules Rₛ. In an embodiment, the molecular system 10 described herein may be the molecules 118 sandwiched at the junction.

While wires 112, 114 are depicted as having substantially circular cross-sections in FIGS. 3A and 3B, it is to be understood that other cross-sectional geometries are contemplated as being within the purview of the present disclosure, such as, for example, ribbon-like geometries, substantially rectangular geometries, substantially square geometries, non-regular geometries, and the like.

Further, the wires 112, 114 may be modulation-doped by coating their surfaces with appropriate molecules—either electron-withdrawing groups (Lewis acids, such as boron trifluoride (BF₃)) or electron-donating groups (Lewis bases, such as alkylamines) to make them p-type or n-type conductors, respectively. FIG. 4B depicts a coating 120 on wire 112 and a coating 122 on wire 114. The coatings 120, 122 may be modulation-doping coatings, tunneling barriers (e.g., oxides), or other nano-scale functionally suitable materials. Alternatively, the wires 112, 114 themselves may be coated with one or more R species 116; and, where the wires cross, Rₛ 118 is formed. Or yet alternatively, the wires 112, 114 may be coated with molecular species 120, 122, respectively, for example, that enable one or both wires 112, 114 to be suspended to form colloidal suspensions. Details of such coatings are provided in U.S. Pat. No. 6,459,095, entitled “Chemically Synthesized and Assembled Electronic Devices”, issued Oct. 1, 2002, to James R. Heath et al, the disclosure of which is incorporated herein by reference in its entirety.

Embodiments of the molecular system 10 are advantageously switchable between four states and are capable of exhibiting different hues. The molecular system 10 is versatile in that it is capable of optical and/or electrical switching. Furthermore, the size of the molecular systems 10 may range from nanometers to micrometers, making them suitable for use in a variety of optical and/or electronic devices.

While several embodiments have been described in detail, it will be apparent to those skilled in the art that the disclosed embodiments may be modified. Therefore, the foregoing description is to be considered exemplary rather than limiting.

What is claimed is:

1. A molecular system that is reversibly switchable between four states, the molecular system comprising:
at least two ends;
at least three rotors located between the at least two ends, each of the at least three rotors capable of rotating when under the influence of an electric field having a predetermined strength, the predetermined strength of the electric field for rotating one of the at least three rotors being different than that of the predetermined strength of the electric field for rotating each of an other of the at least three rotors;
at least two stators located between the at least two ends; and
at least one conjugated connecting unit linking at least one of the at least three rotors and at least one of the at least two stators;
wherein rotation of at least one of the at least three rotors switches the molecular system to one of the four states.

2. The molecular system as defined in claim 1 wherein each of a first state, a second state, and a third state of the molecular system is an OFF state and wherein a fourth state of the molecular system is an ON state.

3. The molecular system as defined in claim 2 wherein the at least three rotors and the at least two stators are in a coplanar conformation in the ON state, and wherein at least one of the at least three rotors and the at least two stators are in a non-planar conformation in the OFF state.

4. The molecular system as defined in claim 1 wherein the molecular system is substantially colorless in a first state, and wherein the molecular system exhibits substantially different hues in each of a second state, a third state, and a fourth state.

5. The molecular system as defined in claim 1 wherein each of the at least three rotors has an electron-accepting group and an electron-donating group.

6. The molecular system as defined in claim 5 wherein the electron-accepting group comprises at least one of hydrogen; hetero atoms including at least one of N, O, S, P, F, Cl, and Br; functional groups containing at least one of the hetero atoms; saturated hydrocarbons; unsaturated hydrocarbons; substituted hydrocarbons; carboxylic acids; carboxylic esters; carboxylic amides; nitro groups; nitrites; carbonyls; cyano groups; imines; azo groups; sulfuric acids; sulfuric esters; sulfuric amides; phosphoric acids; phosphoric esters; phosphoric amides; and mixtures thereof.

7. The molecular system as defined in claim 5 wherein the electron-donating group comprises at least one of functional groups containing at least one hetero atom including at least one of B, Si, I, N, O, S, and P; hydrogen; amines; OH; SH; ethers; saturated hydrocarbons; unsaturated hydrocarbons; substituted hydrocarbons; and mixtures thereof, and wherein the electron-donating group is more electropositive than the electron-accepting group.

8. The molecular system as defined in claim 1, further comprising a plurality of conjugated connecting units linking at least one of the at least three rotors and at least one of the at least two stators.

9. The molecular system as defined in claim 1 wherein at least one of the at least three rotors has two angularly offset sides, with at least one conjugated connecting unit attached to each of the offset sides, and wherein each of the at least one conjugated connecting units is attached to one of the at least two stators.

10. The molecular system as defined in claim 1 wherein there are at least four stators, at least six conjugated connecting units, and each of the at least three rotors has two angularly offset sides, with one of the at least six connecting units attached respectively to each of the offset sides, and wherein each of the at least six conjugated connecting units is attached to one of the at least four stators.

11. The molecular system as defined in claim 10 wherein the molecular system has at least one connecting group attached at each of the at least two ends, and wherein at least two of the at least four stators has one of the connecting groups attached thereto at a position distal to one of the at least six conjugated connecting units.

12. A method for reversibly switching a molecular system between four states, the method comprising:
subjecting the molecular system to an electric field having a first predetermined strength, thereby rotating one of at least three rotors in the molecular system such that the one of the at least three rotors is non-planar with at least two stators in the molecular system, and switching the molecular system from a first state to a second state;
subjecting the molecular system to an electric field having a second predetermined strength, thereby rotating a second of the at least three rotors such that the second of the at least three rotors is non-planar with the at least two stators, and switching the molecular system from the second state to a third state; and
subjecting the molecular system to an electric field having a third predetermined strength, thereby rotating a third of the at least three rotors such that the third of the at least three rotors is non-planar with the at least two stators, and switching the molecular system from the third state to a fourth state.

13. The method as defined in claim 12 wherein the third predetermined strength is different than the second predetermined strength, and wherein the second predetermined strength is different than the first predetermined strength.

14. The method as defined in claim 13 wherein the third predetermined strength is greater than the second predetermined strength, and wherein the second predetermined strength is greater than the first predetermined strength.

15. The method as defined in claim 12 wherein the first state of the molecular system is in an ON state and wherein each of the second state, the third state, and the fourth state of the molecular system is in an OFF state.

16. The method as defined in claim 15 wherein the molecular system is substantially colorless in the fourth state, and wherein the molecular system exhibits a blue hue in the third state, a green hue in the second state, and a red hue in the first state.

17. A molecular switching device, comprising:
at least one bottom electrode;
at least one top electrode, the top electrode crossing the bottom electrode at a non-zero angle, thereby forming a junction; and
a molecular system operatively disposed in the junction, the molecular system including:
at least two ends;
at least three rotors located between the at least two ends, each of the at least three rotors capable of rotating when subjected to an electric field having a predetermined strength, the predetermined strength of the electric field for rotating one of the at least three rotors being different than that of the predetermined strength of the electric field for rotating each of an other of the at least three rotors;
at least two stators located between the at least two ends; and
at least one conjugated connecting unit linking at least one of the at least three rotors and at least one of the at least two stators;
wherein rotation of at least one of the at least three rotors switches the molecular system to one of four states.

18. The molecular switching device as defined in claim 17 wherein each of a first state, a second state, and a third state of the molecular system is in an OFF state and wherein a fourth state of the molecular system is in an ON state.

19. The molecular switching device as defined in claim 18 wherein the at least three rotors and the at least two stators are in a coplanar conformation in the ON state, and wherein at least one of the at least three rotors and the at least two stators are in a non-planar conformation in the OFF state.

20. The molecular switching device as defined in claim 17 wherein the molecular system is substantially colorless in a first state, and wherein the molecular system exhibits substantially different hues in each of a second state, a third state, and a fourth state.
